(19) United States
(12) Patent Application Publication
(10) Pub. No.: US 2009/0320911 A1
(43) Pub. Date: Dec. 31, 2009

(54) METHOD AND SYSTEM FOR IMPROVING CONDUCTIVITY OF NANOTUBE NETS AND RELATED MATERIALS

(76) Inventor: Rodney Ruoff, Austin, TX (US)

Correspondence Address: HULSEY IP INTELLECTUAL PROPERTY LAWYERS, P.C., 919 Congress Avenue, Suite 919, AUSTIN, TX, 78701, US

(21) Appl. No.: 12/491,794

(22) Filed: Jun. 25, 2009

Related U.S. Application Data
(63) Continuation-in-part of application No. 12/233,436, filed on Sep. 18, 2008.
(60) Provisional application No. 60/973,249, filed on Sep. 18, 2007.

(51) Int. Cl. H01L 31/0256; B05D 5/12; B05D 3/00; B05D 3/06; B32B 9/00

(52) U.S. Cl. 136/252; 427/113; 427/532; 427/553; 428/408; 977/742

(57) ABSTRACT

A method and system for improving the electrical conductivity of the nodes of a nanotube net and related materials. A method for adding material to the nodes of a nanotube net that provides more pathways and connections to guarantee good electrical conductance between one electrode and another and speeds the transmission of charge carriers by providing alternative pathways. These improvements may include an enhanced overall thermal conductivity of the CNT net and enhanced mechanical performance of the CNT net. The present disclosure improves, either independently or jointly, electrical, thermal, or mechanical properties of CNT nets. Further, optical transmission does not worsen significantly.

### CROSS REFERENCE TO RELATED APPLICATIONS

This U.S. patent application is a continuation-in-part of pending U.S. patent application Ser. No. 12/233,436 filed Sep. 18, 2008 entitled, “METHOD AND SYSTEM FOR IMPROVING CONDUCTIVITY AND MECHANICAL PERFORMANCE OF CARBON NANOTUBE NETS AND RELATED MATERIALS” by inventor Rodney Ruoff, which claims the benefit of priority of U.S. Provisional Patent Application No. 60/973,249, filed Sep. 18, 2007, entitled, “METHOD AND SYSTEM FOR IMPROVING CONDUCTIVITY AND MECHANICAL PERFORMANCE OF CARBON NANOTUBE NETS AND RELATED MATERIALS” by inventor Rodney Ruoff, which is incorporated herein by reference in its entirety.

### TECHNICAL FIELD

This disclosure relates in general to the field of thin films, and more particularly to thin films composed of networks of carbon nanotubes (“CNT nets”), and even more particularly to electrical conductivity, thermal conductivity, and mechanical performance of thin films composed of CNTs.

### BACKGROUND

Substantial literature exists describing carbon nanotube nets and the electrical, thermal, or mechanical performance of CNT nets (also at times referred to as “bucky paper”, “carbon nanotube thin films”, “transparent conductive films composed of carbon nanotubes” and so on).

A CNT net is defined as being comprised of nodes and segments. A CNT net has transparency and sheet resistance attributes that compare favorably with other materials. The overall electrical resistance of CNT nets composed primarily of randomly oriented and crossed CNTs is largely determined by the resistance at the nodes, the crossing points of the CNTs.

A major limitation of CNT net thin films for applications is their relatively high electrical resistance. The main reason that CNT nets do not have a significantly higher electrical conductivity is because the impedance at the nodes (where two different CNTs intersect) is significantly larger than the impedance of the segments of CNTs away from the nodes. In short, the electrical conductivity of the straight CNT segments is much larger than the electrical conductivity in the node regions.

The nature of the weak bonding at the node of CNT nets is of the van der Waals type. The weak adhesion at the node means that the mechanical performance is typically controlled by sliding at the node regions. The nature of the bonding at the node plays a central role in the mechanics of CNT nets. A need exists, therefore, for improving the local CNT net mechanics performance beyond what has been achieved to date.

In the same vein, high node thermal resistance limits the thermal conductivity of CNT nets below that of the segments. Despite the high thermal conductivity of the individuals CNTs, the nodes have a high thermal resistance. A need exists, therefore, for improving the local thermal conductivity at the nodes so as to improve the overall thermal conductivity of the CNT net.

A random assembly of CNTs in the form of a CNT net may be viewed as a new electronic material that offers several fundamental advantages for transparent and electronic applications. Transparent conductive films (“TCFs”) may be created from 1-D nanostructures such as CNTs. One example application is a network of CNTs deposited by any of a number of methods (spray-coating, screen-printing, by filtering them from a dispersion of them in a solvent, etc.), with a goal of maximizing the electrical conductivity and minimizing the absorbance of light.

TCFs are electrically conductive thin films and are of tremendous technological and economic importance in a broad array of existing and future applications. The dominant factor in the performance of TCFs is the electrical resistance at the node (the region where two CNTs cross each other, and are in physical proximity to each other). A need exists, therefore, for a TCF which is designed to account for this dominant performance factor.

TCFs may be implemented for various applications including, but not limited to, solar cells, solid state lighting, still-image recorders, lasers, optical communication devices, electrodes in flexible electrodes, sensitive bolometers for IR, smart windows, defrosting windows, touch screens, chemical sensor, wearable electronic device, and radio frequency identification (“RFID”) tags.

A CNT net that is fabricated with an improved conductivity without diminishing transmittance could mean that solar cells would be more efficient with more light reaching the active part of the cell, and with charge carriers being more efficiently collected. A further need exists for a network of CNTs which maximizes transmittance and electrical conductivity.

Indium tin oxide (“ITO”) has been widely used as an electrode materials in optoelectronic devices because of its high conductivity, good transmittance, and suitable work function. However, currently used TCFs such as indium tin oxide (ITO) have drawbacks such as cost and mechanical limitations. Additionally, the supply of indium has been depleting. A need exists, therefore, for potential replacement materials to address the drawbacks of currently used TCFs.

### BRIEF SUMMARY OF THE INVENTION

A method and system for adding material to enhancing the electrical conductivity in a nanotube net, where improving the electrical conductivity of the nodes greatly improves the overall electrical conductivity of the CNT net. More concretely and with the example of improved electrical performance: An improved CNT net provides more pathways and connections to guarantee good electrical conductance between one electrode and another, speeds the transmission of charge carriers by providing alternative pathways, and provides enhanced fabrication and manufacturability. In the same regard, adding material to enhance the node electrical conductivity of a nanotube that greatly improves the overall thermal conductivity of the CNT net is disclosed. In the same regard, adding material to enhance the node electrical conductivity of a nanotube that greatly improves the overall mechanical performance of the CNT net is disclosed. These improvements, either singly or jointly, may thus include greater electrical conductivity, greater thermal conductivity, greater mechanical performance, and an improved fault tolerance, among others. The present disclosure improves, either independently or jointly, electrical, thermal, or mechanical properties of CNT nets. In accordance with the disclosed subject matter, a method and system for adding conductive material in a CNT net is provided that deposits material at the nodes of a CNT net, which may increase the diameter of the nodes and that will enhance the electrical conductive path in the CNT net. Once a region of conductive material is deposited at the nodes of a CNT net, better conductive pathways of a subset of nanotubes in such a CNT net may be achieved.

The present disclosure teaches at least one node in a CNT net that arises from the physical proximity of a subset of nanotubes in a CNT. Further, nanotubes that do not have bonding of the van der Waals type could be brought into van der Waals type bonding through the present disclosure. The CNT net may provide greater transmission of electrical current to an electrode. More specifically, the improved CNT net enhances the electrical conductance. Further, thermal conductivity is enhanced. Further, optical transmission does not worsen significantly.

These and other advantages of the disclosed subject matter, as well as additional novel features, will be apparent from the description provided herein. The intent of this summary is not to be a comprehensive description of the claimed subject matter, but rather to provide a short overview of some of the subject matter's functionality.

### BRIEF DESCRIPTION OF DRAWINGS

The features, nature, and advantages of the disclosed subject matter may become more apparent from the detailed description set forth below when taken in conjunction with the drawings in which like reference characters identify correspondingly throughout and wherein:

FIG. 1 illustrates two crossed carbon nanotubes (CNTs).

FIG. 2 shows a perspective close-up of the node of two crossed CNTs.

FIG. 3 displays the addition of material at the node of two crossed CNTs to enhance the node electrical conductivity.

FIG. 4 illustrates an electrical conductive pathway that provides transmission of electrical current from one electrode to another electrode.

FIG. 5 shows an embodiment of the mechanism of capillary forces to deposit material to enhance the node electrical conductivity.

FIG. 6 provides a schematic of coated metal nanoparticles on the junction of two crossed CNTs.

### DETAILED DESCRIPTION OF THE ILLUSTRATED EMBODIMENTS

In describing embodiments of the present invention illustrated in the drawings, specific terminology is employed for the sake of clarity.

In the present disclosure, the word “nanotube” may be a quasi-1D nano-structure with at least one dimension being less than 100 nanometers and consisting of, but not limited to, a nanotube (“NT”), a nanowire (“NW”), or a nanoribbon. Examples may include, but are not limited to, silicon nanowires, germanium nanowires, boron nitride nanowires, and boron carbide nanowires. The benefits of the present disclosure can be derived from essentially any nanotube, such as the ones previously defined.

Carbon nanotube nets or CNT nets are defined as a random network of CNTs, such as in thin film form. The disclosed subject matter focuses on CNT nets, but it is understood that the individual elements of the nanotube network of interest could be NWs, NTs, or nanoribbons of other material composition than carbon, so long as the individual elements are either good electrical conductors, or thermal conductors, or both; or that have good mechanical properties as individual elements.

The present disclosure describes a nanostructured network where at least one interconnected path provides a conducting channel between two electrodes.

Further, the disclosed subject matters focuses primarily on electrical conductivity, but it is to be understood that the concepts presented also allow significant improvement in thermal conductivity, and also of mechanical performance of the CNT nets, when appropriately implemented.

The disclosed subject matter significantly improves upon prior art of CNT nets, by improving the transparent electrically conductive thin film performance by reducing the contact resistance (the node impedance) at the nodes in the CNT nets.

The disclosed subject matter significantly improves upon prior art of CNT nets, by improving the thermal conductivity by lowering the thermal resistance at the nodes.

The disclosed subject matter significantly improves upon prior art of CNT nets and does not substantially worsen the optical transmission. The material deposited at the nodes may be optically transparent and may have a beneficial effect on electrical conductivity, or it may have some absorption and/or scattering of light that may otherwise transmit through the overall CNT net. The porosity of CNT nets, which are considered as transparent conductive films, is such that absorption/scattering of light by small particles that do absorb and/or scatter light in the wavelength regime of interest may not significantly reduce the overall transmission through the CNT net.

The disclosed subject matter significantly improves upon prior art of CNT nets by optimizing mechanical properties, such as, but not limited to, durability, elasticity, flexibility, strength, toughness, and fatigue by replacing the weak van der Waals bonding with more robust chemical bonding. Improving the mechanical properties of CNT nets provides additional benefits for their subsequent use in myriad applications, such as filtering and embedding in structural materials including as a component for enhancing the properties of composites, among others.

As noted above, the dominant factor in the performance of TCFs is the electrical resistance at the node (the region where two CNTs cross each other, and are in close proximity to each other). The disclosed subject matter provides methods of lowering the contact resistance at the nodes in the network.

An embodiment of the current invention presents concepts for improving the electrical conductivity of thin films composed of CNT nets. CNT nets fabricated to date have a conductivity of at least 400 S/cm.

Another embodiment of the current invention presents concepts for improving the thermal conductivity of thin films composed of CNT nets. CNT nets mathematically modeled to date have a thermal conductivity of at least 0.7 W/mK.

Another embodiment of the current invention presents concepts for improving the mechanical performance of thin films composed of CNT nets. CNT nets fabricated to date have a Young's moduli of at least 0.2 percent of the modulus of single-walled nanotubes.

Another embodiment of the current invention presents concepts for improving the electrical conductivity and the thermal conductivity of thin films composed of CNT nets.

Another embodiment of the current invention presents concepts for improving the electrical conductivity or the thermal conductivity of thin films composed of CNT nets.

Another embodiment of the current invention presents concepts for improving the electrical conductivity and the mechanical performance of thin films composed of CNT nets.

Another embodiment of the current invention presents concepts for improving the electrical conductivity or the mechanical performance of thin films composed of CNT nets.

Another embodiment of the current invention presents concepts for improving the thermal conductivity and the mechanical performance of thin films composed of CNT nets.

Another embodiment of the current invention presents concepts for improving the thermal conductivity or the mechanical performance of thin films composed of CNT nets.

Another embodiment of the current invention presents concepts for improving the electrical conductivity, thermal conductivity, and the mechanical performance of thin films composed of CNT nets.

Another embodiment of the current invention presents concepts for improving the electrical conductivity, or the thermal conductivity, or the mechanical performance of thin films composed of CNT nets.

Another embodiment of the current invention presents concepts for improving the electrical conductivity and thermal conductivity, or the mechanical performance of thin films composed of CNT nets.

Another embodiment of the current invention presents concepts for improving the electrical conductivity and mechanical performance, or the thermal conductivity of thin films composed of CNT nets.

Another embodiment of the current invention presents concepts for improving the thermal conductivity and mechanical performance, or the electrical conductivity of thin films composed of CNT nets.

The foregoing description of the preferred embodiments is not meant to be limiting. The above description of the preferred embodiments is meant to enable any person skilled in the art to make or use the claimed subject matter. Various modifications to these embodiments will be readily apparent to those skilled in the art, and the generic principles defined herein may be applied to other embodiments without the use of the innovative faculty.

The invention is better understood with reference to the accompanying figures in which:

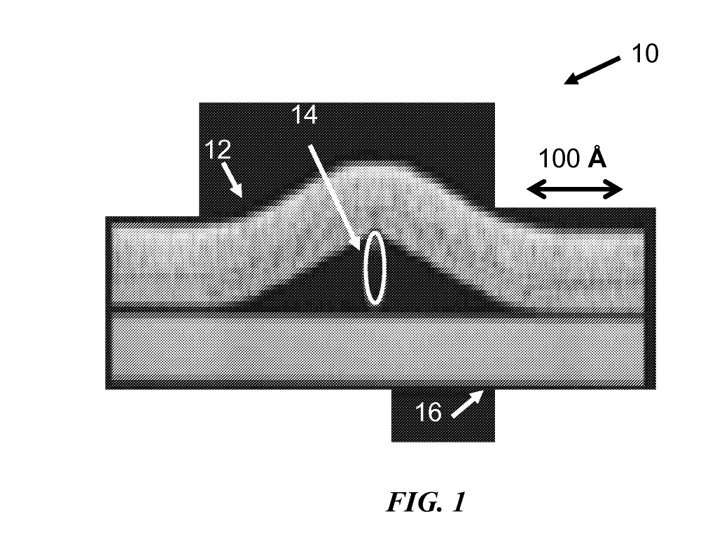

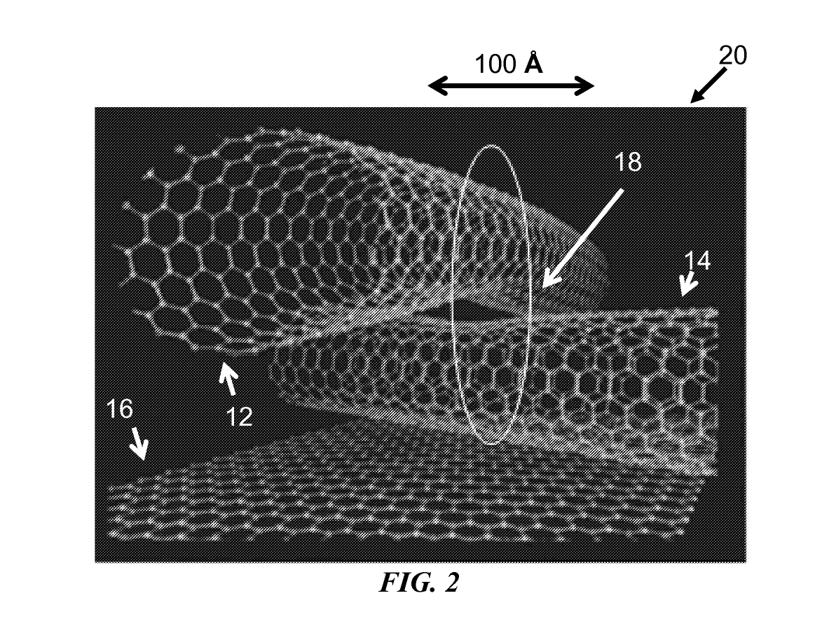

FIGS. 1 and 2 show views 10 and 20 of two crossed single-walled carbon nanotubes 12 and 14. For the purposes of the current disclosure, the underlying graphite surface 16 may be imagined not to be present. Node 18 (highlighted by the white oval) indicates schematically where deposition may occur.

The view 20 shown in FIG. 2 shows a perspective close-up of the crossing point. It shows that both tubes 12 and 14 are deformed elastically near the contact region 18. The force acting on the lower tube 14 is about 5 nN.

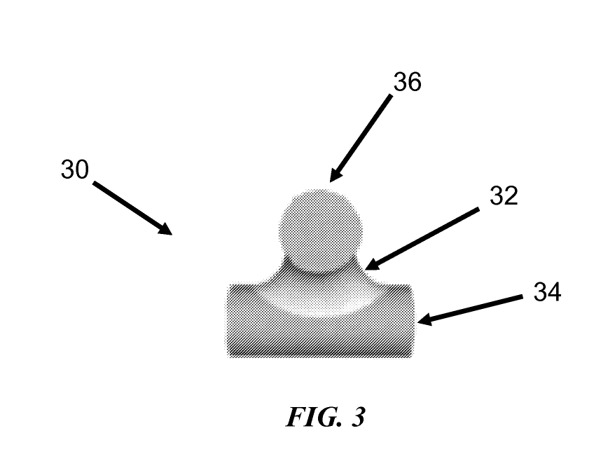

The general concept of depositing a small amount of material at the nodes to lower the node resistance is shown in FIG. 3. View 30 shown in FIG. 3 shows selective deposition of electrically conductive material 32 at the junction of CNT 34 and CNT 36. Without such a deposit, the contact resistance is largely controlled by two CNTs that are weakly linked at the nodes through the weak van der Waals forces, or possibly via “contaminant” residue from the processing used to make the CNTs or in fabricating the CNT net. The “contaminant” residue here may be considered beneficial towards enhancing the electrical node conductivity. It should be understood that the deposit could simply be adsorbed molecules, possibly via a “contaminant” residue from the processing used to make the CNTs or in fabricating the CNT net, that act to lower the resistance at the node.

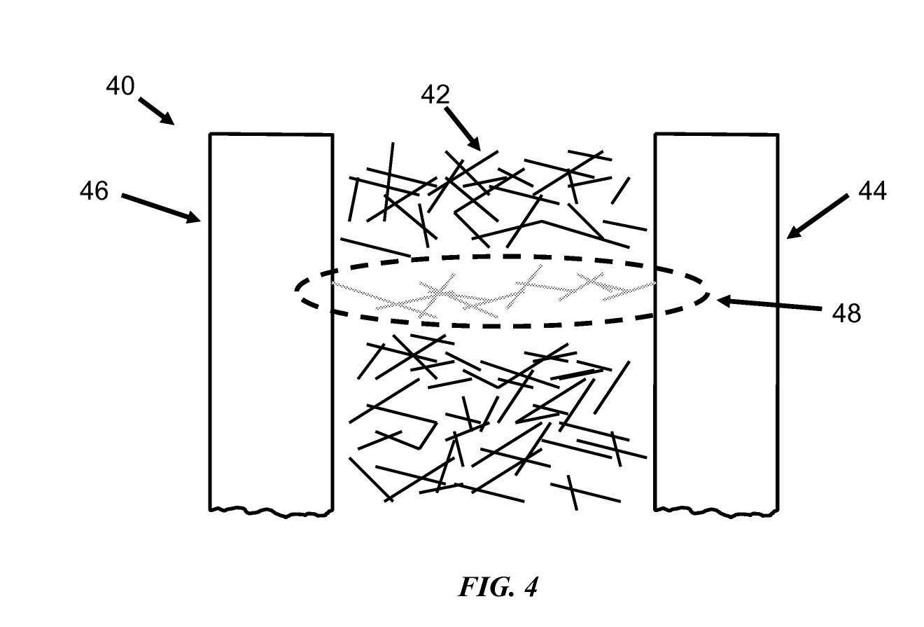

A highly connected CNT network with multiple avenues in the form of an electronic device 40 is shown in FIG. 4. A CNT net 42 with many pathways that influence the transmission of charge carriers and provide alternative routes for current flow. An interconnected set of CNTs from electrode 44 to electrode 46 creates a conducting path 48. The multiple avenues provided by CNT net 42 afford a considerable fault tolerance to failure, leaves many other paths open, and rearrange the pathways for current flow. A web of CNTs would allow the passage of most of the incident light. A network of highly one-dimensional CNT's has high transparency and is advantageous for applications that require light transmission.

For CNT nets with high optical transmittance and low optical reflectance across a broad wavelength range, it would be most desirable to deposit material primarily or only at the node and not elsewhere. However, there might be some situations where molecules are adsorbed more or less equally on segments and junctions have little effect on optical transmission, but due to deposition also at the nodes yield significantly improved electrical conductivity at the nodes. In terms of more selective deposition, consider single-walled carbon nanotubes (SWCNTs) that form the network. The transmittance is lowered if a shell of material uniformly coats all regions of the SWCNT network, provided the material being deposited is not itself non-absorbing for the spectral region of interest. Many (but not all) materials are not transparent in some part of the spectrum; therefore, a part of the disclosed subject matter is directed to methods to deposit material primarily or only at the nodes, lowering the contact resistance dramatically. By lowering the contact resistance of the nodes, the overall (electrical or thermal or both) resistance of the network will be lowered, so that better TCFs may be made. Also, materials may be chosen that optimize the mechanical properties of the nodes so that the mechanical properties of TCFs based on such CNT networks are also optimized.

The following section outlines alternative methods for improving contact resistance at the nodes, as examples of a class of methods that will find use in the future to lower the contact resistance.

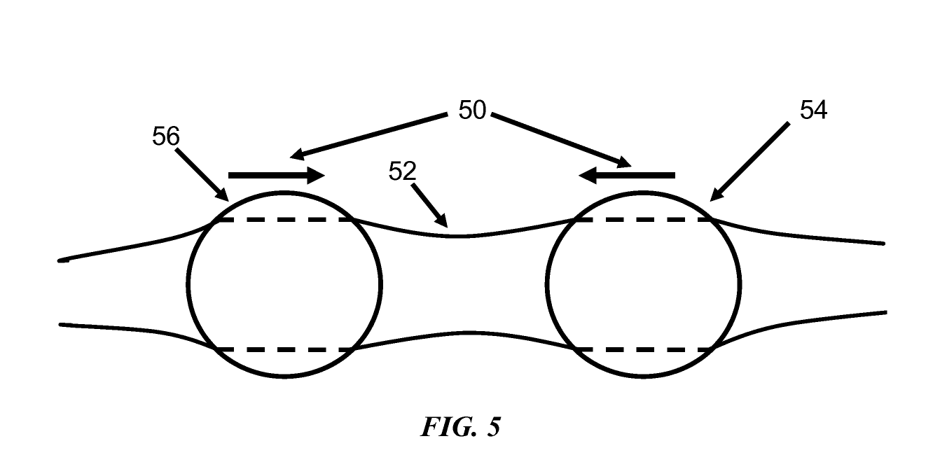

In the preferred embodiment, the mechanism of capillary forces 50 is exploited to deposit material that will substantially increase the electrical conductivity at the node in FIG. 5. The added material is deposited by exploiting drying of a solution or a colloidal or other liquid dispersion. The deposition happens only or primarily at the nodes of the CNT net, due to drying effects (capillary forces). That is, as drying is occurring, the liquid 52 (the solvent) is “drawn” into the node regions, and in the final stages of drying, the solute particle 54 and the solute particle 56 (or colloidal particles if from a colloidal suspension, i.e., a liquid dispersion) is deposited in the node regions. The deformation of the meniscus of the liquid 52 occurs due to proximity between particle 54 and particle 56. The deformation of the meniscus of the liquid 52 results in a net immersive, capillary forces 50 that tend to direct the particles towards one and another. If needed, post-processing (steps such as any of heating to cure the deposit, exposure to light to cure the deposit, exposure to chemical reactants such as from a gas or liquid to convert the deposit to a more appropriate type of deposit with lower electrical resistance, and so on) may be used to yield the lowest electrical resistance deposit also having other favorable attributes such as durability. Alternatively, rather than pre-formed nanoparticles the material deposited might be molecules that will be adsorbed at the node through such capillary forces upon drying.

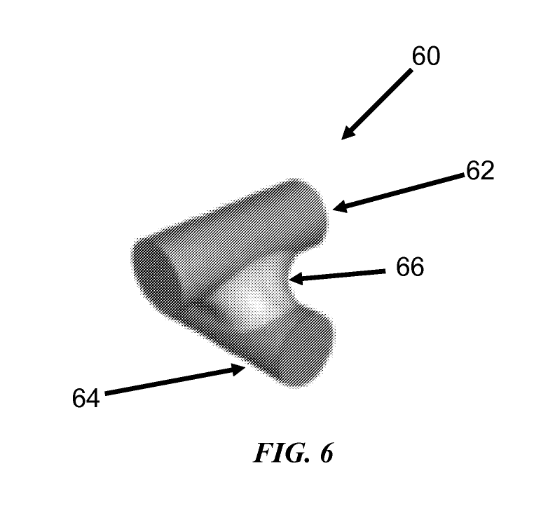

In an alternative embodiment, isolated or randomly grown CNTs 60 that have been coated with metal nanoparticles are shown in FIG. 6. A CNT 62 and a CNT 64 have been coated by either using pre-existing metal nanoparticles or using a metal salt solution followed by reduction. CNTs are selectively coated with metal nanoparticles on the junction 66 of CNT 62 and CNT 64. The metal nanoparticles have a diameter being less than 100 nanometers and consist of, but are not limited to, nickel, iron, gold, platinum, and alloy particles.

An alternative method for depositing such material to enhance the node electrical conductivity includes physisorption, the attachment of non-covalently bonded atoms or molecules or material to a solid-phase surface.

An alternative method for depositing such material to enhance the node electrical conductivity includes chemisorption, the take up and the chemical binding of a substance onto the surface of another substance.

An alternative method for depositing such material to enhance the node electrical conductivity includes electrodeposition either by electroplating or electroless deposition. Optionally, a voltage bias may be applied. The electric field in the vicinity of the node is likely to be substantially higher (a voltage drop across a small separation) than in the segments, allowing for preferential deposition in the node regions.

Another alternative method for depositing such material to enhance the node electrical conductivity includes transient heating of the network through short-time pulses of electrical current. Higher node resistance will result in preferential heating of the nodes compared to the segments, resulting in a temperature difference between nodes and segments. This temperature difference allows for preferential deposition at the nodes. In one embodiment, this deposition results from gaseous reactants that the net is immersed in.

An alternative heating method includes microwave heating, which has been shown to be an effective method for heating CNT nets. Pulses of microwave power may be applied in the presence of a gas which will react primarily in the higher temperature zones; if there is a small liquid drop at each of the nodes but not on the segments, then, microwave heating and thus temperature rise may be accelerated in the node regions, driving the desired deposition.

Another alternative method for depositing such material to enhance the node electrical conductivity includes deposition of carbon atoms (among others), which are likely to surface diffuse along the saturated covalently bonded CNTs, and thus to aggregate at the nodes. There are many other examples of materials that are not particularly effective at wetting the segment section of CNTs, among them gold and others, which are likely to build up in the node regions due to the potential well that favors binding at the nodes versus the segments.

Another alternative method for depositing such material to enhance the node electrical conductivity includes deposition via chemical reactions which preferentially take place at the nodes, due to the close proximity of the CNTs. Reactants with the appropriate geometry and energetic considerations cross-link the crossed CNTs at the nodes, or wrap around the nodes, or are deposited preferentially at the nodes. For example, the deposition of appropriately sized (thus, relatively small lateral dimension) graphene-based nano-flakes from liquid suspensions so that the nano-flakes deposit primarily onto the nodes and also conform well by wrapping onto/around the nodes, is likely to enhance conductivity through a greater surface area of contact between the crossed CNTs and the overlying graphene-based nano-flakes.

Another method of achieving selective deposition at the nodes is through electrophoresis or dielectrophoresis, where the electric field gradient is sharply varied in the node region, and is used to deposit, e.g., nanoparticles selectively at the nodes.

In the embodiments outlined above, a small amount of material to enhance the node electrical conductivity is deposited. In an alternative method, a small amount of thermally conductive material is deposited to enhance the node thermal conductivity. In the embodiments outlined above, if the material deposited is also a good thermal conductor or acts to lower the thermal resistance, then this will enhance the thermal conductivity of the CNT net. However, it should be noted that the material need not be electrically conductive. For example, boron nitride nanotubes have exceptional thermal conductivity; because of their large electrical band gap, these nanotubes are going to be, as a random network, highly transmitting for visible light. This serves as an example of a thermally conductive NT net capable of substantial further improvements by reducing thermal resistance at the nodes. Some good thermal conductors are also good electrical conductors, so the possibilities exist for improving the thermal and electrical conductivity, or the thermal or electrical conductivity, by deposition of the appropriate type of material.

Another alternative method for improving contact resistance at the nodes involves deposition of a small amount of material to enhance mechanical performance. By removing the constraint of achieving good transparency for optical wavelengths, some coating of the segments, in addition to improving the mechanical connection at the nodes, may be allowed.

The above are given as representative of examples of what are likely to be many methods of depositing material at the nodes so as to improve dramatically the electrical, thermal, or mechanical performance (or both, or all three) of such CNT nets and similar types of networks comprised of quasi-1D nanowires or nanotubes. By judicious use of appropriate chemical reactants and processing conditions (temperature, other reactants, flow, light, time, etc.), the node impedance may be lowered significantly compared to the prior art, and/or the mechanical performance may be significantly enhanced.

The improved CNT net here disclosed may function in electronic, photoemissive, and photovoltaic devices, including solar cells, solid state lighting, still-image recorders, lasers, optical communication devices, electrodes in flexible electrodes, sensitive bolometers for IR, smart windows, defrosting windows, touch screens, chemical sensor, wearable electronic device, and radio frequency identification (RFID) tags. In addition, the various embodiments discussed heretofore may be combined, altered, and practiced differently than as taught herein. The inventors expect those with ordinary skill in the art to make variations upon the basic principles taught in the present disclosure.

In summary, the present disclosure teaches a method and system for improving conductivity and mechanical performance of CNT nets and related materials. A method for adding material to enhance the electrical conductivity at the nodes of CNT nets. A system for enhanced electrical conductance between one electrode and another, transmission of charge carriers by providing alternative pathways, and fabrication and manufacturability.

The foregoing description of the preferred embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for adding material to enhance the electrical conductivity in a nanotube net, said method comprising the steps of:
accessing a nanotube net comprising a plurality of nanotubes, wherein a subset of nanotubes of said plurality of nanotubes form a plurality of nodes, said nodes arising from physical proximities of said subset of nanotubes;
depositing material for enhancing electrical conductivity of at least a portion of said nanotube net among said plurality of nodes;
increasing the diameter of said plurality of nodes;
forming an electrical conductive path, said path arising from enhanced electrical conductivity among said subset of nanotubes.

2. The method of adding material to enhance the node electrical conductivity in a nanotube net of claim 1, said method further comprising the step of drying of a solution by using capillary forces to draw said material into said plurality of nodes.

3. The method of adding material to enhance the node electrical conductivity in a nanotube net of claim 1, said method further comprising the step of physisorption of said material into said plurality of nodes.

4. The method of adding material to enhance the node electrical conductivity in a nanotube net of claim 1, said method further comprising the step of chemisorption of said material into said plurality of nodes.

5. The method of adding material to enhance the node electrical conductivity in a nanotube net of claim 1, said method further comprising the step of adsorption of said material into said plurality of nodes.

6. The method of adding material to enhance the node electrical conductivity in a nanotube net of claim 1, said method further comprising the step of applying a voltage bias in the vicinity of said plurality of nodes to preferentially place said material in said plurality of nodes.

7. The method of adding material to enhance the node electrical conductivity in a nanotube net of claim 1, said method further comprising the step of generating short-time pulses of electrical current to transiently heat said plurality of nodes more than said nanotube net.

8. The method of adding material to enhance the node electrical conductivity in nanotube net of claim 1, said method further comprising the step of microwave heating said plurality of nodes in the presence of a gas.

9. The method of adding material to enhance the node electrical conductivity in a nanotube net of claim 1, said method further comprising the step of diffusing said material along said nanotube net to build up said material at said plurality of nodes.

10. The method of adding graphene-based nano-flakes to enhance the node electrical conductivity in a nanotube net of claim 1, said method further comprising the step of applying nanostructures from liquid suspensions to conform at said plurality of nodes, said nanostructures comprising structures from the group consisting essentially of graphene-based flakes, graphene-based platelets, graphene-based sheets, graphene-based nano-flakes, graphene-based nano-platelets, and graphene-based nano-sheets.

11. The method of adding material to enhance the node electrical conductivity in a nanotube net of claim 1, said method further comprising the step of heating directly said plurality of nodes to fuse said material to said plurality of nodes.

12. A nanotube net comprising:
a plurality of nanotubes, wherein a subset of nanotubes of said plurality of nanotubes form a plurality of nodes, said nodes arising from physical proximities of said subset of nanotubes;
a region of deposited material to enhance the node electrical conductivity at said plurality of nodes.

13. The nanotube net in claim 12, wherein said plurality of nodes comprises a greater diameter of deposition of said material.

14. The nanotube net in claim 12, wherein said subset of nanotubes form an electrical conductive path, said path arising from enhanced electrical conductivity among said subset of nanotubes.

15. The nanotube net in claim 12, wherein said subset of nanotubes comprises said material to enhance the node electrical conductivity drawn into said plurality of nodes.

16. The nanotube net in claim 12, wherein said subset of nanotubes comprises said material to enhance the node electrical conductivity physisorbed into said plurality of nodes.

17. The nanotube net in claim 12, wherein said subset of nanotubes comprises said material to enhance the node electrical conductivity chemisorbed into said plurality of nodes.

18. The nanotube net in claim 12, wherein said subset of nanotubes comprises biased voltage in the vicinity of said plurality of nodes.

19. The nanotube net in claim 12, wherein said subset of nanotubes comprises transiently heated said plurality of nodes.

20. The nanotube net in claim 12, wherein said subset of nanotubes comprises microwave heated said plurality of nodes.

21. The nanotube net in claim 12, wherein said subset of nanotubes comprises diffused said ‘material to enhance the node electrical conductivity’ along said nanotube net.

22. The nanotube net in claim 12, wherein said subset of nanotubes comprises graphene-based sheets conformed to said plurality of nodes.

23. The nanotube net in claim 12, wherein said subset of nanotubes comprises directly heated said plurality of nodes.

24. A system comprising a plurality of nanotube nets for providing transmission of electrical current to an electrode, wherein said plurality of nanotube nets comprises at least one nanotube net.

25. The system of claim 24, wherein said system comprises a solar cell.

26. The system of claim 24, wherein said system comprises a solid state lighting device.

27. The system of claim 24, wherein said system comprises a flexible electronic display.

28. The system of claim 24, wherein said system comprises an optical communication device.

29. The system of claim 24, wherein said system comprises a bolometer.

30. The system of claim 24, wherein said system comprises a radio frequency identification tag.

31. The system of claim 24, wherein said system comprises a smart window.

32. The system of claim 24, wherein said system comprises a chemical sensor.

33. The system of claim 24, wherein said system comprises a wearable electronic device.
